(19) United States
(12) Patent Application Publication
(10) Pub. No.: US 2009/0285413 A1
(43) Pub. Date: Nov. 19, 2009

(54) WORKSTATION PRIVACY APPARATUS

(75) Inventor: Geoff Roesch, Brooklyn, NY (US)

Correspondence Address: FROMMER LAWRENCE & HAUG, 745 FIFTH AVENUE- 10TH FL., NEW YORK, NY, 10151, US

(73) Assignee: IDEA VAULT, LLC, Jackson, WY (US)

(21) Appl. No.: 12/306,448

(22) PCT Filed: Aug. 25, 2007
(86) PCT No.: PCT/IB2007/004533

§ 371 Date: Dec. 23, 2008

Related U.S. Application Data
(60) Provisional application No. 60/816,477, filed on Jun. 26, 2006.

(51) Int. Cl. H03G 3/00; H04R 1/00; E06B 7/00

(52) U.S. Cl. 381/104; 381/384; 49/70

(57) ABSTRACT

The present invention is a two way communication system for employees who work in an open office environment, and lack the privacy of an office door. The system performs the same functions as a real door, allowing the user to “alert” fellow employees to their availability status without being interrupted throughout the day. In addition, it allows the user to record interoffice memos, and allows other employees to record messages for the user when he or she is not at the desk. This valuable tool is a great asset for people in open office environments, which greatly increases the quality of work product by limiting interruptions.

### RELATED APPLICATION

The application claims the benefit of provisional application 60/816,477 filed Jun. 26, 2006 which is hereby incorporated by reference in its entirety herein.

### FIELD OF INVENTION

The present invention relates to a device for use on desk tops that communicates the work status and mood of the individual at the desk and their availability or need for privacy. The ability to non-verbally communicate this information eliminates unwanted interruptions and improves work productivity. Additionally, by using this invention when away from the desk, individuals can communicate their whereabouts and time of return, as well as capture messages from missed visitors by means of the invention's inter-office message recording device.

### BACKGROUND OF THE INVENTION

Dealing with interruptions while working at your desk breaks focus and productivity. Unless you are in a room with a locked door, nearly all interruptions must be fended off verbally. For desk workers everywhere, whether in the office or at home, the ability to non-verbally communicate mood, availability or need for privacy is critical in achieving high work efficiency. The demographic most affected by desk interruptions is the growing number of open-office workers, now nearly 20 million in the US alone. In fact, almost 80% of workers spend their time in cubicles or modular open office environments. These types of office designs provide pseudo-privacy at best and are not conducive to stopping spontaneous interruptions.

In surveys conducted by HR Magazine, the #1 complaint of open office workers is that of being interrupted by random and spontaneous communications. Bosti Associates, an office research company, reports that open-office workers are interrupted an average of 16 times a day by chatty visitors or unprompted in-person questions from co-workers. Research indicates that it takes approximately 2.9 minutes to regain focus from even just a brief interruption, equaling more than an hour a day trying to simply refocus: more time than that if you calculate the length of the interruption itself.

Working from a database of 13,000 people in 40 organizations, Bosti Associates identified the two most important predictors of job performance; one of them being the ability to perform distraction-free work. When this factor was addressed, individual work performance jumped 4-5%, team performance 23% and overall job satisfaction rose to 23%. Due to space restrictions, flexibility, and the need for cost-effective workspace, businesses continue to choose modular or open office designs, perpetuating the need for desk workers to be able to non-verbally communicate their work-status, availability or need for privacy.

### SUMMARY OF THE INVENTION

With the number of door-less, open-office environments continuing to grow and, with them, interruptions that disrupt worker performance more than an hour a day, there is a critical need for a device that communicates an individual's work status, availability or need privacy. Desk Door answers this need with and all-in-one, non-verbal communication system that enables users to communicate their work status, availability and need for privacy without interrupting their focus. With the Desk Door, an individual can use and combine at least five forms of outbound communication including but not limited to: 1) the opening and closing of the door, 2) writing a personalized message on an erasable area of the device, 3) choosing from pre-written status message insert chips, 4) writing their own status message using blank insert chips and 5) recording their own outbound message for inter-office visitors to hear. Additionally, when the status message indicates that the user is away from his or her desk, the device's audio recording feature can capture inter-office messages from coworkers who visited the user's desk when he or she was away.

### BRIEF DESCRIPTION OF THE DRAWINGS

For a more complete understanding of the invention, reference is made to the following descriptions and accompanying drawings, in which:

FIG. 1 is a front view of a privacy apparatus showcasing the available features of non-verbal communication.

FIG. 2 is a rear view of a privacy apparatus detailing a user's interaction with the apparatus.

FIG. 3 is a cross sectional view of a privacy apparatus detailing the front view with the door in the open position.

### DETAILED DESCRIPTION OF THE INVENTION

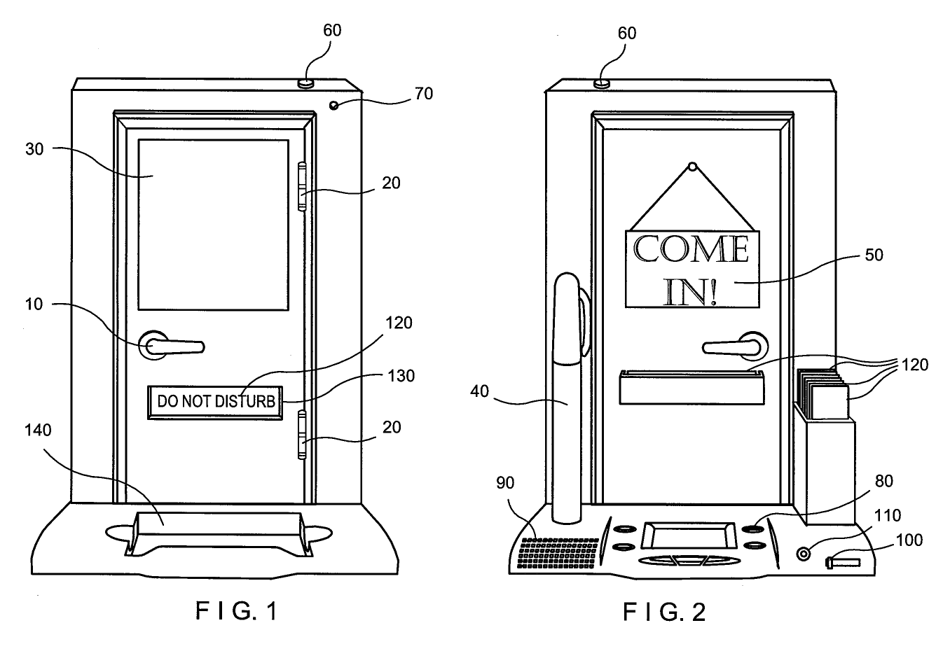

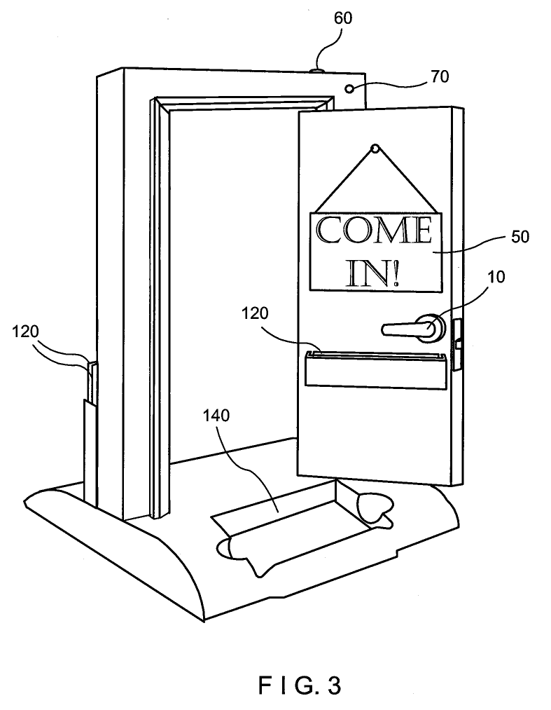

The object of the present invention is to communicate a person's availability or need for privacy, thus achieving the same effect as a full sized office door. The scale replica Desk Door can be opened or closed using a handle 10 or other attachment via hinges 20, magnets, or similar structures. A closed door shows that you are busy and not to be disturbed, See FIG. 1, while an open door invites others to “come in”, See FIG. 3. The Desk Door can take shape of all manner of door types including but not limited to: an office door, security gate, jail door, castle door, garden gate, or other doorway, gate or entrance structure with the added features of:

A writing surface on the front of the door 30 to write customized messages with an erasable writing device 40, and a “come in” display on the rear of the door 50, displayed when the door is in the open position, See FIG. 3.

A record button 60 with a microphone 70 to capture incoming inter-office messages, and a memo button 80 to record outgoing inter-office messages

A speaker 90 to replay messages with a volume control 100 to control the level of audio output.

A headphone jack 110 to allow for private listening

A selection of status message insert chips 120, offering both a variety of prewritten message chips as well as blank message chips for personalized messages detailing the user's privacy or availability status.

A status window 130 to view the status message insert chips.

A tray to hold and display business cards 140

While this embodiment includes an audio recorder 60, another embodiment lacks a recorder, giving flexibility in the complexity and cost of the system.

While this embodiment includes an erasable message surface 30, another embodiment has a digital screen capable of connecting to a computer and downloading and displaying images from the internet, and images from additional software.

Thus, while fundamental novel features of the invention are shown and described and pointed out, it will be understood that various omissions and substitutions and changes in the form and details of the devices illustrated, and in their operation, may be made by those skilled in the art without departing from the spirit of the invention. For example, it is expressly intended that all combinations of those elements and/or method steps which perform substantially the same function in substantially the same way to achieve the same results are within the scope of the invention. Moreover, it should be recognized that structures and/or elements and/or method steps shown and/or described in connection with any disclosed form or embodiment of the invention may be incorporated in another form or embodiment. It is the intention, therefore, to be limited only as indicated by the scope of the claims appended hereto.

What is claimed is:

1. A scale replica door-shaped, two-way communication system for a desktop comprising an audio recording mechanism, a microphone, at least one speaker, status message insert chips, and an erasable writing surface.

2. The system of claim 1 wherein said system further comprises a hinge, magnet, or other appropriate mechanism for allowing the door to be placed in an open or closed position.

3. The system of claim 1 wherein said system further comprises a handle, or other structure that facilitates opening and closing the door.

4. The system of claim 1 wherein users can write and erase status messages on the erasable writing surface using an erasable writing instrument.

5. The system of claim 1 wherein said writing surface comprises a digital screen used to display downloaded images from the internet or from a software program.

6. The system of claim 1 wherein said audio recording device can record incoming messages and store said messages for playback.

7. The system of claim 5 wherein said audio recording device further comprises a button which, when depressed, records audio messages.

8. The system of claim 1 wherein said speaker replays recorded audio messages.

9. The system of claim 1 further comprising an area to store and display business cards

10. The system of claim 1 further comprising an area to display prewritten status messages.

11. The system of claim 1 which comprises a volume control to adjust the volume of the sound output.

12. The system of claim 1 which comprises a headphone jack to allow for private listening of audio messages.
